(19) United States
(12) Patent Application Publication
(10) Pub. No.: US 2025/0236951 A1
(43) Pub. Date: Jul. 24, 2025

(54) SUBSTRATE PROCESSING METHOD AND SUBSTRATE PROCESSING APPARATUS

(71) Applicant: Tokyo Electron Limited, Tokyo (JP)

(72) Inventors: Yuta NAKANE, Miyagi (JP); Sho KUMAKURA, Miyagi (JP); Takeshi KATAHIRA, Miyagi (JP); Takahiro YONEZAWA, Miyagi (JP)

(73) Assignee: Tokyo Electron Limited, Tokyo (JP)

(21) Appl. No.: 19/082,337

(22) Filed: Mar. 18, 2025

Related U.S. Application Data
(63) Continuation of application No. PCT/JP2023/034347, filed on Sep. 21, 2023.

(30) Foreign Application Priority Data
Oct. 4, 2022 (JP) 2022-160473
Oct. 4, 2022 (JP) 2022-160475

(51) Int. Cl. C23C 16/455; C23C 16/30; C23C 16/56

(52) U.S. Cl. CPC C23C 16/45536; C23C 16/30; C23C 16/56

(57) ABSTRACT

A substrate processing method includes: (a) providing a substrate, (b) supplying a first processing gas containing an amino group and silicon to the substrate to form a first layer on the substrate, and (c) causing a second processing gas containing a metal halide-containing gas to react with the first layer to form a metal-containing film.

### CROSS-REFERENCE TO RELATED APPLICATIONS

This application is a bypass continuation application of international application No. PCT/JP2023/034347 having an international filing date of Sep. 21, 2023, and designating the United States, the international application being based upon and claiming the benefit of priority from Japanese Patent Applications No. 2022-160473 and No. 2022-160475, filed on Oct. 4, 2022, the entire contents of each are incorporated herein by reference.

### TECHNICAL FIELD

Exemplary embodiments of the present disclosure relate to a substrate processing method and a substrate processing apparatus.

### BACKGROUND

PTL 1 discloses a film forming method of forming a tungsten film. In this method, a SiH₄ gas is supplied into a chamber, and a SiH₄ gas treatment is performed on a substrate on which an underlying film is formed. Thereafter, a tungsten chloride gas and a reducing gas are sequentially supplied into the chamber while purging an interior of the chamber in the course of sequentially supplying the tungsten chloride gas and the reducing gas, so as to form a tungsten film.

### CITATION LIST

### Patent Documents

PTL 1: JP2017-186595A

### SUMMARY

The present disclosure provides a technique of forming a metal-containing film at a low temperature.

In one exemplary embodiment, a substrate processing method includes: (a) providing a substrate, (b) supplying a first processing gas containing an amino group and silicon to the substrate to form a first layer on the substrate, and (c) causing a second processing gas containing a metal halide-containing gas to react with the first layer to form a metal-containing film.

According to one exemplary embodiment, a technique of forming the metal-containing film at a low temperature is provided.

### BRIEF DESCRIPTION OF DRAWINGS

FIG. 1 is a diagram schematically illustrating a substrate processing apparatus according to one exemplary embodiment.

FIG. 2 is a diagram schematically illustrating the substrate processing apparatus according to one exemplary embodiment.

FIG. 3 is a flowchart of a substrate processing method according to one exemplary embodiment.

FIG. 4 is a cross-sectional view of an example of a substrate to which the method of FIG. 3 may be applied.

FIG. 5 is a cross-sectional view illustrating one step of the substrate processing method according to one exemplary embodiment.

FIGS. 6A to 6D are diagrams illustrating examples of a structural formula of aminosilane.

FIG. 7 is a cross-sectional view illustrating one step of the substrate processing method according to one exemplary embodiment.

FIG. 8 is a cross-sectional view illustrating one step of the substrate processing method according to one exemplary embodiment.

FIG. 9 is a diagram illustrating an example of a reaction process in which a tungsten-containing film is formed.

FIG. 10 is a cross-sectional view illustrating one step of the substrate processing method according to one exemplary embodiment.

FIG. 11 is a diagram illustrating a plasma processing apparatus according to one exemplary embodiment.

FIG. 12 is a cross-sectional view of an example of a substrate to which the method of FIG. 3 may be applied.

FIG. 13 is a cross-sectional view illustrating one step of a substrate processing method according to one exemplary embodiment.

FIG. 14 is a cross-sectional view illustrating one step of the substrate processing method according to one exemplary embodiment.

FIG. 15 is a cross-sectional view illustrating one step of the substrate processing method according to one exemplary embodiment.

FIG. 16 is a cross-sectional view of an example of a substrate in a first experiment.

FIG. 17 is a cross-sectional view of an example of a substrate in a third experiment.

FIG. 18 is a graph illustrating an example of a depth and a CD of a recess in the first experiment.

FIG. 19 is a graph illustrating an example of a depth and a CD of a recess in a fourth experiment.

### DETAILED DESCRIPTION

Hereinafter, various exemplary embodiments will be described in detail with reference to the drawings. Further, like reference numerals will be given to like or corresponding parts throughout the drawings.

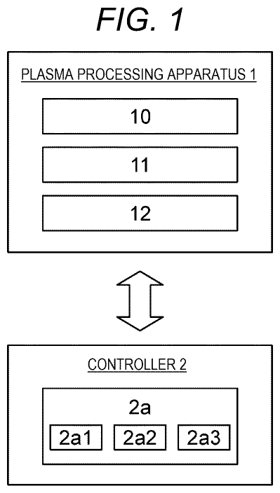

FIG. 1 is a diagram illustrating an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions that cause the plasma processing apparatus 1 to execute various steps described in the present disclosure. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2 or may be acquired via a medium when necessary. The acquired program is stored in the storage 2a2, read from the storage 2a2 by the processor 2al, and executed thereby. The medium may be any of various recording media readable by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The controller 2 may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry includes hardware that carries out or is programmed to perform the recited functionality. The hardware may be any hardware disclosed herein which is programmed or configured to carry out the recited functionality.

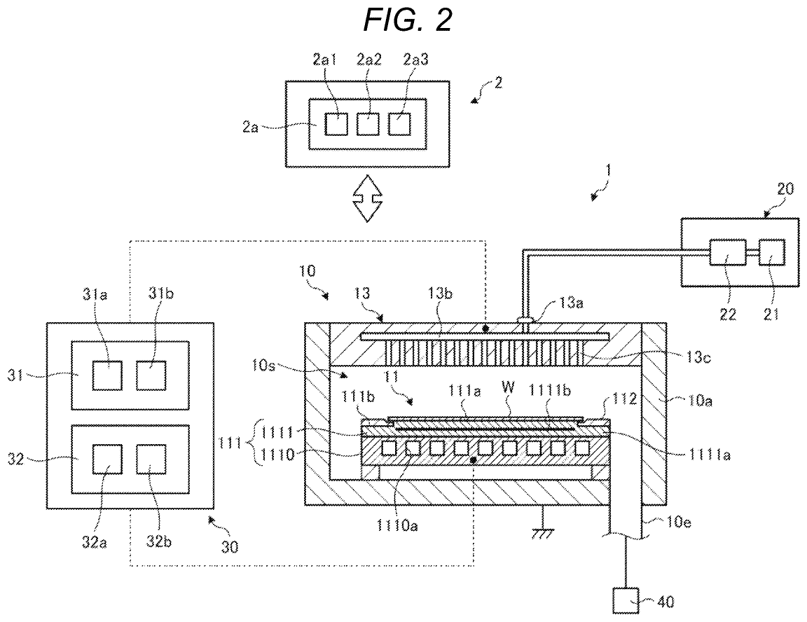

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, the at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may further include a temperature control module configured to adjust a temperature of at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

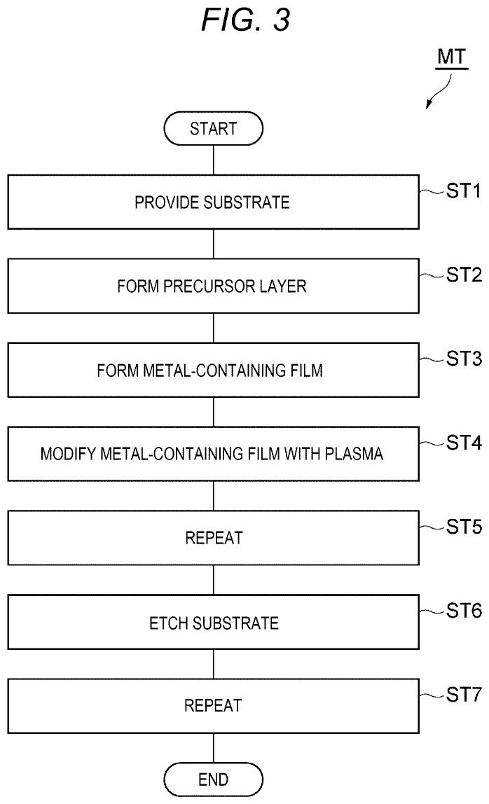

FIG. 3 is a flowchart of a substrate processing method according to one exemplary embodiment. A substrate processing method MT illustrated in FIG. 3 (hereinafter referred to as a “method MT”) may be executed by the plasma processing apparatus 1 in the embodiment. The method MT may be applied to a substrate W.

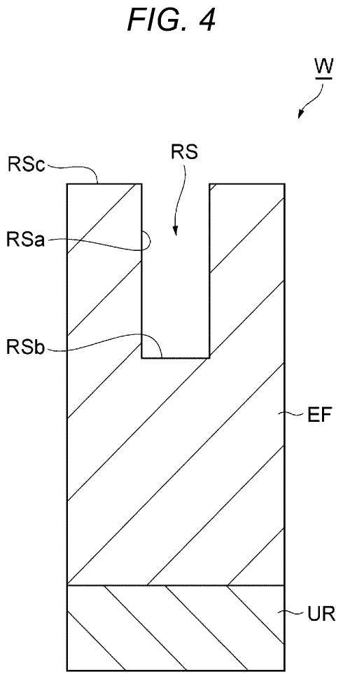

FIG. 4 is a cross-sectional view of an example of the substrate to which the method of FIG. 3 may be applied. As shown in FIG. 4, in one embodiment, the substrate W includes a film EF. The film EF may be an etching target film. The substrate W may include an underlying region UR below the film EF.

The film EF may include at least one of a silicon-containing film and a carbon-containing film. The silicon-containing film may include at least one of a silicon film, a silicon oxide film, a silicon nitride film, and a silicon oxynitride film. The film EF may be a single film or a stacked film.

The film EF may have a pattern. The pattern may include a recess RS or a projection. The pattern may include a plurality of recesses RS or a plurality of projections. Hereinafter, an example in which the film EF includes the recess RS will be described. The recess RS may have a hole pattern or a line pattern. The recess RS may have a sidewall RSa, a bottom RSb, and an upper surface RSc connected to an upper end of the sidewall RSa. A dimension (critical dimension: CD) of the recess RS may be 100 nm or less, or may be 50 nm or less. The dimension of the recess RS is a minimum value of a length of the recess RS in a direction orthogonal to a depth direction of the recess RS.

Hereinafter, the method MT will be described by taking as an example a case where the method MT is applied to the substrate W using the plasma processing apparatus 1 in the embodiment described above, with reference to FIGS. 3 to 11. In a case where the plasma processing apparatus 1 is used, the method MT may be performed in the plasma processing apparatus 1 under the control of each part of the plasma processing apparatus 1 by the controller 2. In the method MT, as illustrated in FIG. 2, the substrate W on the substrate support 11 disposed in the plasma processing chamber 10 is processed.

As illustrated in FIG. 3, the method MT may include step ST1 to step ST7. Step ST1 to step ST7 may be performed sequentially. The method MT may not include at least one of step ST4, step ST5, and step ST7. The method MT may not include at least one of step ST4 and step ST5. Step ST4 may be performed between step ST2 and step ST3.

### Step ST1

In step ST1, the substrate W illustrated in FIG. 4 is provided. The substrate W may be provided in the plasma processing chamber 10. The substrate W may be supported by the substrate support 11 in the plasma processing chamber 10. The underlying region UR may be disposed between the substrate support 11 and the film EF.

### Step ST2

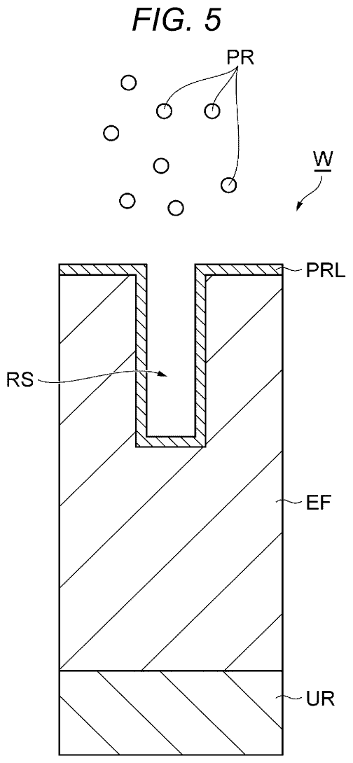

In step ST2, as illustrated in FIG. 5, a precursor gas PR is supplied to the substrate W to form a precursor layer PRL on the substrate W. The precursor gas PR is an example of a first processing gas. The precursor layer PRL is an example of a first layer. The precursor layer PRL may be formed on the recess RS. The supply of the precursor gas PR may be started at the start of step ST2, and the supply of the precursor gas PR may be stopped at the end of step ST2.

The precursor gas PR contains an amino group and silicon. The amino group may be substituted. The amino group is represented by, for example, a —NR¹R². Each of R¹ and R² represents hydrogen or a hydrocarbon. The hydrocarbon may contain a nitrogen atom, an oxygen atom, and a halogen atom. The precursor gas PR may contain an aminosilane gas. Since reactivity of the aminosilane gas is relatively low, handling is easy. The precursor gas PR may contain an aminosilane gas having 1 to 4 amino groups. The precursor gas PR may contain at least one typical element among hydrogen (H), boron (B), carbon (C), oxygen (O), nitrogen (N), phosphorus (P), and sulfur(S). The typical element may be in a hydrocarbon of an amino group. The precursor gas PR may contain an aminosilane gas containing carbon.

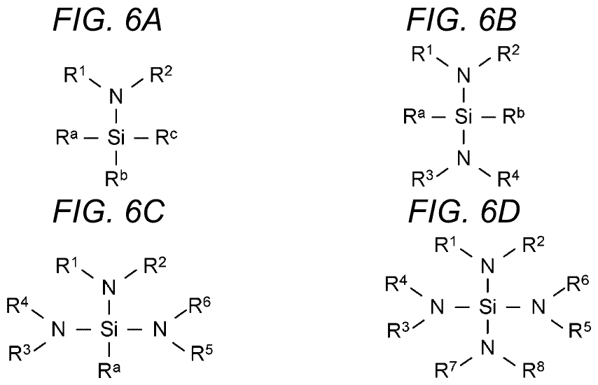

FIGS. 6A to 6D are diagrams illustrating examples of a structural formula of aminosilane. In FIGS. 6A to 6D, each of R¹ to R⁸ and R^{a} to R^{c} represents hydrogen or a hydrocarbon. The hydrocarbon may contain a nitrogen atom, an oxygen atom, and a halogen atom. FIG. 6A represents an aminosilane having one amino group. FIG. 6B represents an aminosilane having two amino groups. FIG. 6C represents an aminosilane having three amino groups. FIG. 6D represents an aminosilane having four amino groups.

Examples of the aminosilane include butylaminosilane (BAS), bis-tertiarybutylaminosilane (BTBAS), dimethylaminosilane (DMAS), bisdimethylaminosilane (BDMAS), tridimethylaminosilane (TDMAS), diethylaminosilane (DEAS), bisdiethylaminosilane (BDEAS), dipropylaminosilane (DPAS), diisopropylaminosilane (DIPAS), hexakisethylaminodisilane, a compound represented by formula (1) ((R1R2)N)ₙSi_{X}H_{2X+2-n-m}(R3)ₘ, and a compound represented by formula (2) ((R1R2)N)ₙSi_{X}H_{2X-n-m}(R3)ₘ.

In formula (1) and formula (2), n is a natural number of 1 to 6 as the number of amino groups. m is 0 or a natural number of 1 to 5 as the number of alkyl groups. R1, R2, or R3 is CH₃, C₂H₅, or C₃H₇. R1, R2, and R3 may or may not be the same as each other. R3 may be Cl or F. X is a natural number of 1 or more.

The precursor gas PR may further contain at least one selected from the group consisting of a hydrogen gas, a SiH₄ gas, a Si₂H₆ gas, a BH₃ gas, and a B₂H₆ gas. These gases may be supplied at different timings from the precursor gas PR.

The precursor gas PR may further contain a silane gas that does not contain an amino group, in addition to the aminosilane gas. Examples of disilane or higher silane-based gases that do not contain amino groups include a silicon hydride represented by a formula SiₘH₂ₘ₊₂ (where m is a natural number of 2 or more) and a silicon hydride represented by a formula SiₙH₂ₙ (where n is a natural number of 3 or more).

Examples of the silicon hydride represented by the formula SiₘH₂ₘ₊₂ include disilane (Si₂H₆), trisilane (Si₃H₈), tetrasilane (Si₄H₁₀), pentasilane (Si₅H₁₂), hexasilane (Si₆H₁₄), and heptasilane (Si₇H₁₆).

Examples of the silicon hydride represented by the formula SiₙH₂ₙ include cyclotrisilane (Si₃H₆), cyclotetrasilane (Si₄H₈), cyclopentasilane (Si₅H₁₀), cyclohexasilane (Si₆H₁₂), and cycloheptasilane (Si₇H₁₄).

The precursor gas PR may further contain an inert gas. Examples of the inert gas include the noble gases.

In step ST2, a temperature of the substrate support 11 may be 300° C. or lower, 150° C. or lower, or 120° C. or lower. A temperature of the substrate support 11 may be 60° C. or higher or may be 90° C. or higher.

In step ST2, plasma may be generated from the precursor gas PR, or plasma may not be generated from the precursor gas PR.

The precursor layer PRL may be formed on the sidewall RSa, the bottom RSb, and the upper surface RSc of the recess RS. The precursor layer PRL may contain a group containing silicon atoms and hydrogen or a hydrocarbon (e.g., a —SiR^{a}R^{b}R^{c}). The precursor layer PRL may be formed by the precursor gas PR bonding or reacting with a surface of the recess RS through adsorption, CVD, or PVD.

### Step ST3

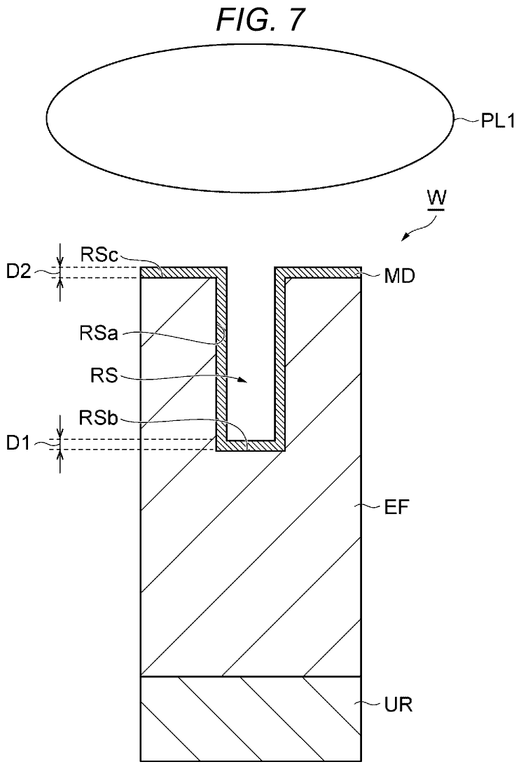

In step ST3, as illustrated in FIG. 7, a modification gas is reacted with the precursor layer PRL to form a metal-containing film MD. The modification gas is an example of a second processing gas. The supply of the modification gas may be started at the start of step ST3, and the supply of the modification gas may be stopped at the end of step ST3.

The modification gas contains a metal halide-containing gas. The metal halide-containing gas may contain at least one of tungsten (W), molybdenum (Mo), titanium (Ti), vanadium (V), platinum (Pt), and cobalt (Co). Examples of the metal halide-containing gas include a tungsten hexafluoride (WF₆) gas, a tungsten hexachloride (WCl₆) gas, a molybdenum hexafluoride (MoF₆) gas, a molybdenum hexachloride (MoCl₆) gas, a titanium tetrachloride (TiCl₄) gas, a vanadium pentafluoride (VFs) gas, and a platinum hexafluoride (PtF₆) gas. A metal contained in the modification gas may substitute for silicon of the substrate W.

The modification gas may further contain an inert gas. Examples of the inert gas include the noble gases. The modification gas may further contain at least one selected from the group consisting of a hydrogen gas, a SiH₄ gas, a Si₂H₆ gas, a BH₃ gas, and a B₂H₆ gas. These gases may be supplied at different timings from the modification gas.

In step ST3, the temperature of the substrate support 11 may be 300° C. or lower, 150° C. or lower, or 120° C. or lower. The temperature of the substrate support 11 may be 60° C. or higher or may be 90° C. or higher.

In step ST3, plasma PL1 may be generated from the modification gas, or the plasma PL1 may not be generated from the modification gas. When the plasma PL1 is generated, the metal-containing film MD may be modified. For example, an impurity concentration in the metal-containing film MD can be reduced. Examples of impurities include hydrogen, boron, carbon, oxygen, phosphorus, and sulfur. Further, a density of the metal-containing film MD can be improved.

In step ST3, the precursor layer PRL may prevent etching of the recess RS by the metal halide-containing gas.

The metal-containing film MD may contain at least one metal among tungsten, molybdenum, titanium, vanadium, platinum, and cobalt. The metal is derived from the metal halide-containing gas. The metal-containing film MD may contain at least one typical element among hydrogen (H), boron (B), carbon (C), oxygen (O), nitrogen (N), phosphorus (P), and sulfur(S). These typical elements are derived from the precursor gas PR. Further, the metal-containing film MD contains the typical elements, so that a film composition different from that of a single metal film is obtained. Therefore, etching resistance is easier to be controlled than with the single metal film. A composition ratio of the metal may be the largest among composition ratios of the elements contained in the metal-containing film MD. A composition ratio of the carbon may be the largest among the composition ratios of the typical elements contained in the metal-containing film MD. The composition ratio of the carbon contained in the metal-containing film MD may be larger than a composition ratio of the oxygen contained in the metal-containing film MD. The composition ratio of the oxygen contained in the metal-containing film MD may be larger than a composition ratio of the nitrogen contained in the metal-containing film MD.

The metal-containing film MD may have a first thickness D1 at the bottom RSb of the recess RS and a second thickness D2 at the upper surface RSc. The first thickness D1 may be smaller than the second thickness D2. By reducing a flow rate of the modification gas, the first thickness D1 can be reduced. Alternatively, the first thickness D1 may be reduced by shortening a supply time of the modification gas (duration of step ST3).

A thickness of the metal-containing film MD may be changed in a depth direction of the recess RS by changing a control parameter in step ST2 or step ST3. The control parameter may be at least one selected from the group consisting of a flow rate of the precursor gas PR in step ST2, a flow rate of the modification gas in step ST3, a pressure in the plasma processing chamber 10 in step ST2, a pressure in the plasma processing chamber 10 in step ST3, a processing time in step ST2, and a processing time in step ST3. For example, if the flow rate of the precursor gas PR in step ST2 or the flow rate of the modification gas in step ST3 is reduced, the thickness of the metal-containing film MD decreases toward the bottom RSb of the recess RS in the depth direction of the recess RS. For example, if the pressure in the plasma processing chamber 10 in step ST2 or the pressure in the plasma processing chamber 10 in step ST3 is increased, the thickness of the metal-containing film MD decreases toward the bottom RSb of the recess RS in the depth direction of the recess RS. For example, if the processing time of step ST2 or the processing time of step ST3 is shortened, the thickness of the metal-containing film MD decreases toward the bottom RSb of the recess RS in the depth direction of the recess RS.

The metal-containing film MD may have electric resistivity of 1000 μΩ·cm or less, may have electric resistivity of 100μΩ·cm to 600 μΩ·cm, or may have electric resistivity of 100 μΩ·cm to 200 μΩ·cm.

### Step ST4

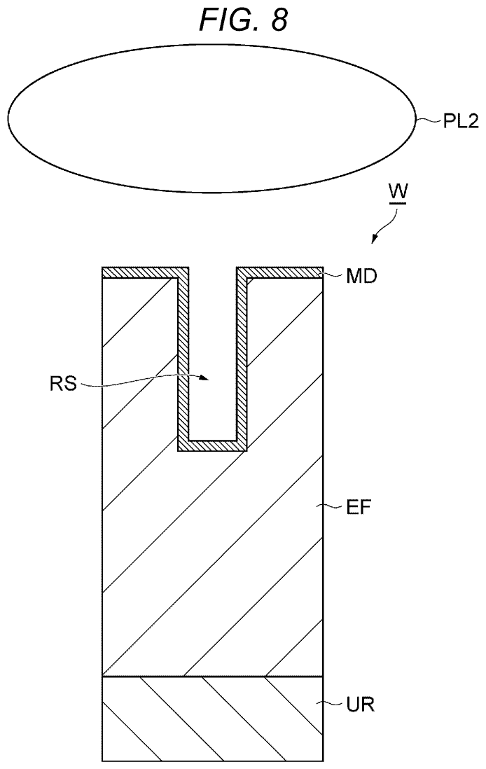

In step ST4, the metal-containing film MD is modified with plasma PL2 as illustrated in FIG. 8. The plasma PL2 may be generated from a processing gas containing at least one of a noble gas, an oxygen-containing gas, and a hydrogen-containing gas. Examples of the oxygen-containing gas include an oxygen gas. Examples of the hydrogen-containing gas include a hydrogen gas.

When a processing gas in step ST4 contains a hydrogen-containing gas, a composition ratio of the elements contained in the metal-containing film MD can be controlled. For example, a composition ratio of the metal and the carbon contained in the metal-containing film MD may be increased by step ST4. When the processing gas in step ST4 contains a hydrogen-containing gas, etching resistance of the metal-containing film MD in step ST6 can be improved. For example, when a third processing gas in step ST6 contains fluorine, the etching resistance of the metal-containing film MD is improved. This is presumed to be because a composition ratio of carbon contained in the metal-containing film MD increases by step ST4.

In step ST4, at least one of RF power, a flow rate of a gas (e.g., a hydrogen-containing gas) that generates active species (e.g., hydrogen radicals) that contribute to the modification, a pressure inside the plasma processing chamber 10, and a processing time may be adjusted. Accordingly, it is possible to control a depth to which the active species enter the recess RS. For example, when the RF power is increased, a plasma density is increased, and the depth to which the active species enter the recess RS can be increased. Alternatively, when the pressure in the plasma processing chamber 10 is increased, the depth to which the active species enter the recess RS can be increased. Alternatively, when the processing time of step ST4 is lengthened, the depth to which the active species enter the recess RS can be increased. By controlling the depth to which the active species enter the recess RS, a portion of the metal-containing film MD formed in an upper region of the sidewall RSa can be selectively modified. For example, the composition ratio of the carbon contained in the metal-containing film MD may be gradually reduced from the upper surface RSc toward the bottom RSb of the recess RS.

### Step ST5

In step ST5, step ST2 to step ST4 are repeated. When step ST4 is not performed, in step ST5, step ST2 and step ST3 are repeated. Purging may be performed in the plasma processing chamber 10 between each step. When the purging is performed, a thickness of the metal-containing film MD can be controlled with high accuracy. In this way, the metal-containing film MD may be formed by atomic layer deposition (ALD).

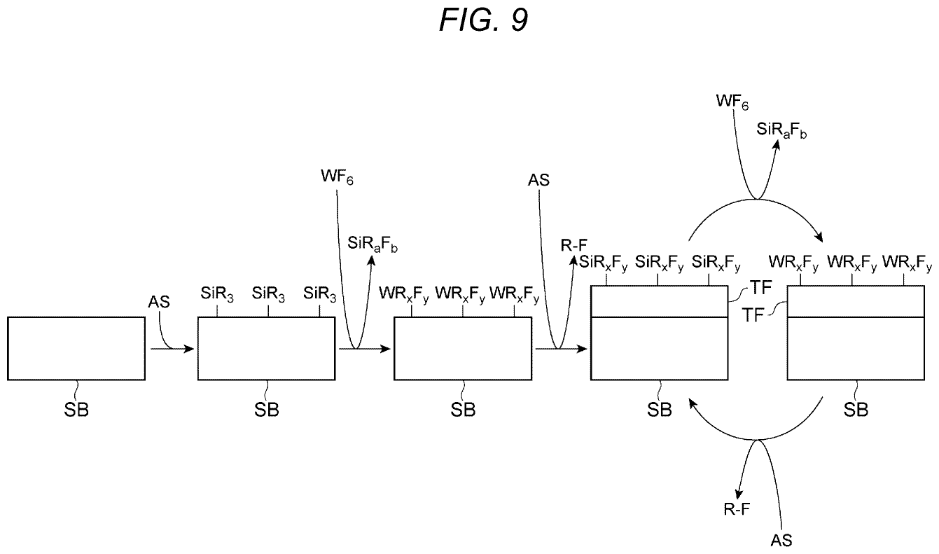

Hereinafter, an example in which a tungsten-containing film is formed as the metal-containing film MD by steps ST2, ST3, and ST5 will be described with reference to FIG. 9. FIG. 9 is a diagram illustrating an example of a reaction process in which a tungsten-containing film is formed. In step ST2, aminosilane AS is supplied to a substrate SB. A precursor layer PRL containing —SiR₃ is formed on a surface of the substrate SB. R is hydrogen or an amino group. In step ST3, a tungsten hexafluoride reacts with the —SiR₃ on the substrate SB to generate SiRₐF_{b}, where a and b are real numbers larger than 0. The SiRₐF_{b} is removed by volatilization. A metal-containing film MD containing —WRₓF_{y} is formed on the substrate SB, where x and y are real numbers larger than 0. In step ST2 of step ST5, the aminosilane AS reacts with the —WRₓF_{y} on the substrate SB to generate R-F. R-F is removed by volatilization. A metal-containing film MD containing a tungsten film TF is generated on the substrate SB. A precursor layer PRL containing —SiRₓF_{y} is generated on a surface of the tungsten film TF. In step ST3 of step ST5, the tungsten hexafluoride reacts with the —SiRₓF_{y} on the substrate SB to generate SiRₐF_{b}. The SiRₐF_{b} is removed by volatilization. A metal-containing film MD containing the tungsten film TF and the —WRₓF_{y} is formed on the substrate SB. By repeating steps ST2 and ST3, the metal-containing film MD becomes thicker.

### Step ST6

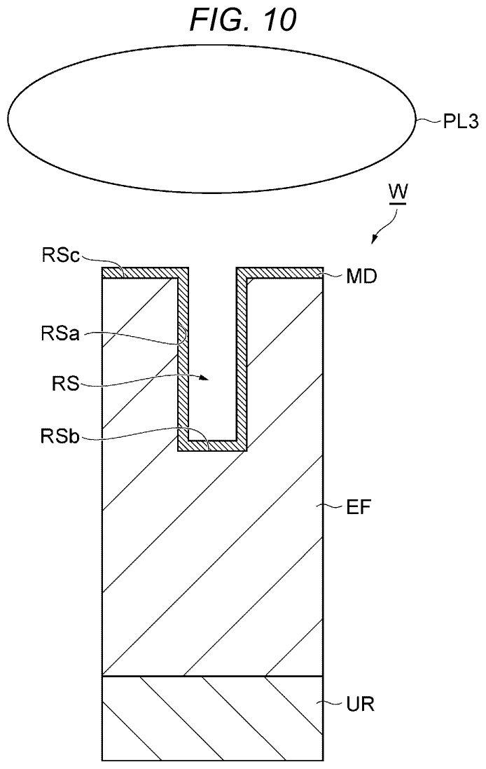

In step ST6, the substrate W is etched with plasma PL3 generated from the third processing gas, as illustrated in FIG. 10. The recess RS may be etched by the plasma PL3. The metal-containing film MD may function as a protective film for etching. The metal-containing film MD may have a function of reinforcing the sidewall RSa and the upper surface RSc during the etching. The third processing gas may contain fluorine. The third processing gas may contain at least one of a fluorocarbon gas and a hydrofluorocarbon gas.

In between step ST5 and step ST6, the metal-containing film MD may have the first thickness D1 at the bottom RSb of the recess RS and the second thickness D2 at the upper surface RSc of the recess RS. In this case, since the bottom RSb of the recess RS is easily etched, the recess RS can be deepened.

### Step ST7

In step ST7, step ST2 to step ST6 are repeated.

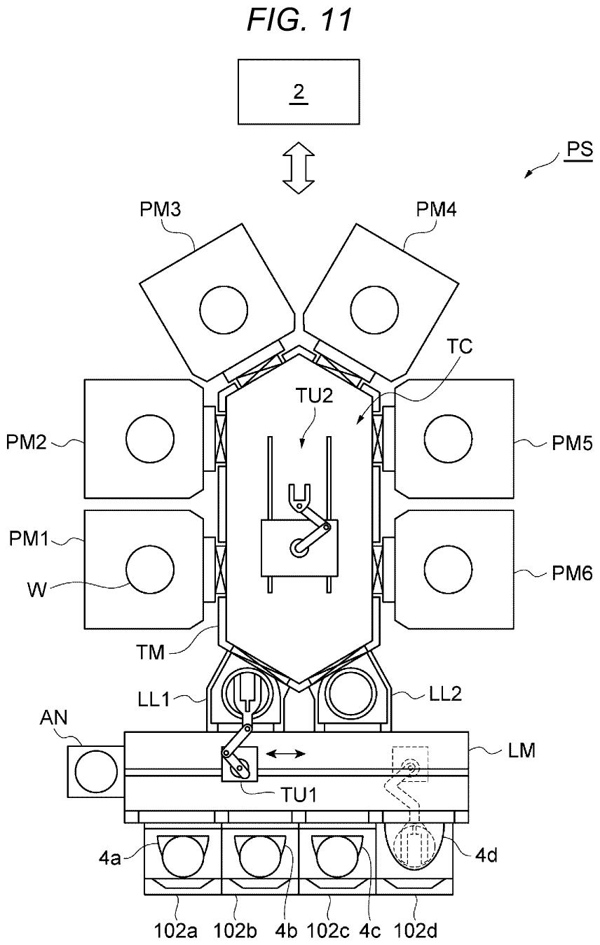

Step ST6 may be performed in a plasma processing chamber (second chamber) different from the plasma processing chamber 10 (first chamber) in which step ST1 to step ST5 are performed. In this case, step ST1 to step ST5 may be performed in a chamber in which no plasma is generated. The method MT may be performed using a plasma processing apparatus PS illustrated in FIG. 11.

FIG. 11 is a diagram illustrating a plasma processing apparatus according to one exemplary embodiment. The plasma processing apparatus PS illustrated in FIG. 11 includes load ports 102a to 102d, containers 4a to 4d, loader module LM, an aligner AN, load-lock modules LL1 and LL2, process modules PM1 to PM6, a transfer module TM, and the controller 2. The number of load ports, number of containers, and number of load-lock modules in the plasma processing apparatus PS can be any one or more. Further, the number of process modules in the plasma processing apparatus PS can be any one or more.

The load ports 102a to 102d are arranged along one edge of the loader module LM. The containers 4a to 4d are placed on the load ports 102a to 102d, respectively. Each of the containers 4a to 4d is, for example, a container referred to as a front opening unified pod (FOUP). Each of the containers 4a to 4d is configured to accommodate a substrate W therein.

The loader module LM has a chamber. A pressure in the chamber of the loader module LM is set to an atmospheric pressure. The loader module LM has a transfer device TU1. The transfer device TU1 is, for example, a transfer robot and is controlled by the controller 2. The transfer device TU1 is configured to transfer the substrate W via the chamber of the loader module LM. The transfer device TU1 can transfer the substrate W between each of the containers 4a to 4d and the aligner AN, between the aligner AN and each of the load-lock modules LL1 and LL2, and between each of the load-lock modules LL1 and LL2 and each of the containers 4a to 4d. The aligner AN is connected to the loader module LM. The aligner AN is configured to adjust a position of the substrate W (calibration of the position).

Each of the load-lock module LL1 and the load-lock module LL2 is disposed between the loader module LM and the transfer module TM. Each of the load-lock module LL1 and the load-lock module LL2 has a preliminary decompression chamber.

The transfer module TM is connected to each of the load-lock module LL1 and the load-lock module LL2 via a gate valve. The transfer module TM has a transfer chamber TC whose interior space can be depressurized. The transfer module TM has a transfer device TU2. The transfer device TU2 is, for example, a transfer robot and is controlled by the controller 2. The transfer device TU2 is configured to transfer the substrate W through the transfer chamber TC. The transfer device TU2 transfers the substrate W between each of the load-lock modules LL1 and LL2 and each of the process modules PM1 to PM6, and between any two process modules among the process modules PM1 to PM6.

Each of the process modules PM1 to PM6 is configured to perform dedicated substrate processing. Step ST1 to step ST5 of the method MT may be performed in a chamber of one of the process modules PM1 to PM6, and step ST6 of the method MT may be performed in a chamber of another one of the process modules PM1 to PM6.

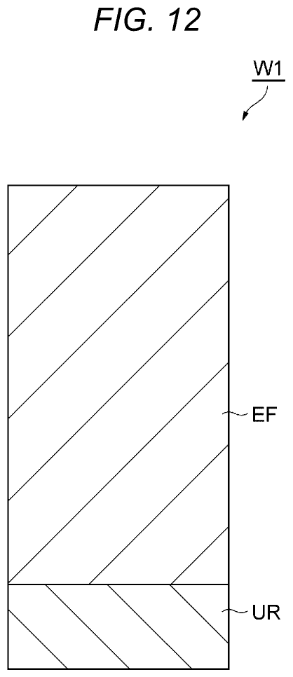

FIG. 12 is a cross-sectional view of an example of a substrate to which the method of FIG. 3 may be applied. The method MT may be applied to a substrate W1 illustrated in FIG. 12. The substrate W1 has the same configuration as the substrate W except that the recess RS is not provided.

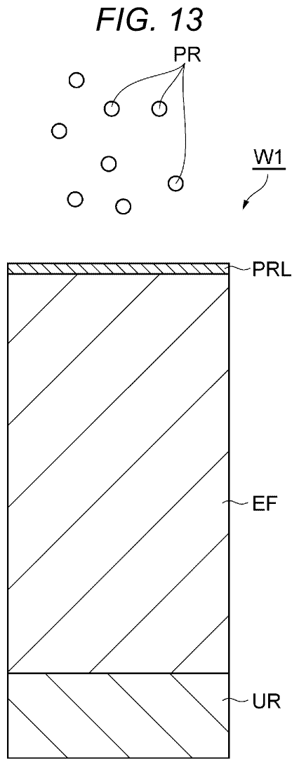

In step ST2, as illustrated in FIG. 13, the precursor gas PR is supplied to the substrate W1 to form the precursor layer PRL on the substrate W1.

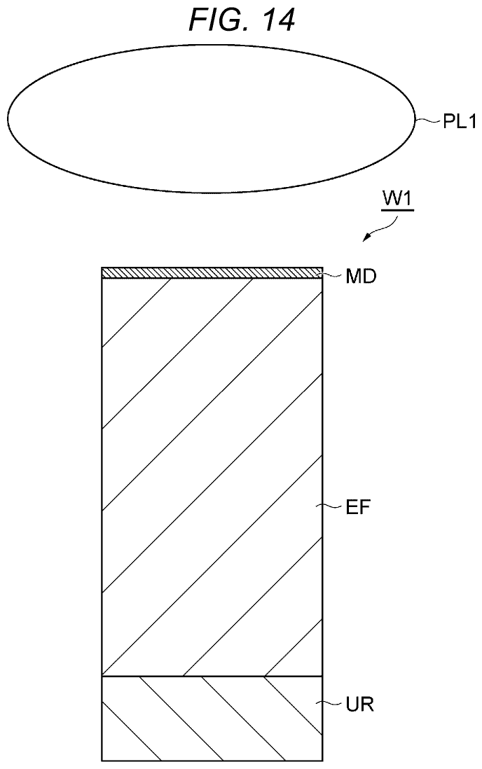

In step ST3, as illustrated in FIG. 14, a modification gas is reacted with the precursor layer PRL to form a metal-containing film MD.

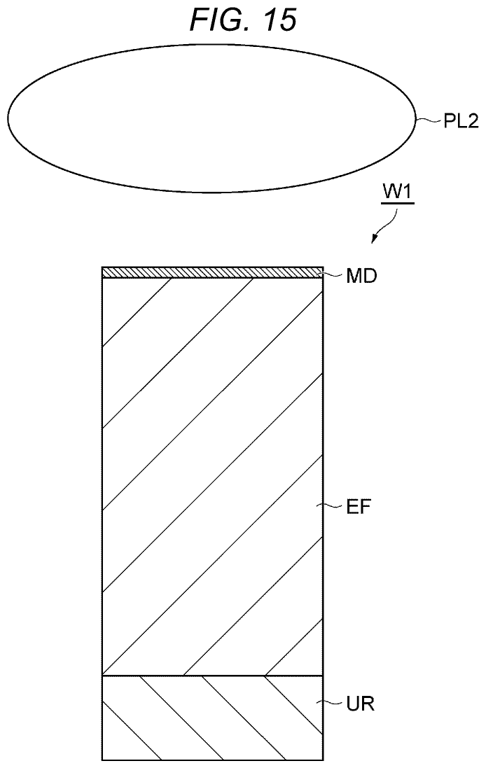

In step ST4, the metal-containing film MD is modified with plasma PL2 as illustrated in FIG. 15.

According to the plasma processing apparatus 1, the plasma processing apparatus PS, and the method MT described above, the precursor layer PRL can be formed at a lower temperature than when the SiH₄ gas is used in step ST2. Accordingly, the metal-containing film MD can be formed at a low temperature. After the metal-containing film MD is formed at a low temperature, the film EF of the substrate W can be etched. Further, by incorporating an element derived from a functional group contained in the precursor gas PR into the metal-containing film MD, variations in a composition of the metal-containing film MD may be increased. For example, when the precursor gas PR contains a functional group including carbon, a metal-containing film MD including carbon can be formed.

Hereinafter, various experiments performed to evaluate the method MT will be described. The following experiments are not intended to limit the present disclosure.

### First Experiment

In a first experiment, a substrate having a recess was prepared. An aminosilane gas containing carbon was supplied to the substrate to form a precursor layer on the recess. Next, the precursor layer was modified with a tungsten hexafluoride gas to form a tungsten-containing film. A step of forming the precursor layer and a step of forming the tungsten-containing film were repeated. A processing time of each step was 20 seconds. The number of cycles was 80. A temperature of the substrate support was 120° C.

### Second Experiment

A second experiment was performed in the same manner as in the first experiment except that the number of cycles was 120.

### Experiment Results

Cross-sections of the substrates obtained in the first experiment and the second experiment were observed. In the first experiment, it was confirmed that a deposited film having a thickness of about 13 nm was formed. In the second experiment, it was confirmed that a deposited film having a thickness of about 16 nm was formed. Further, X-ray photoelectron spectroscopy (XPS) analysis confirmed that the deposited films contained tungsten and carbon. Therefore, it can be understood that when the number of cycles is increased, the tungsten-containing film can be made thicker.

### Third Experiment

A third experiment was performed in the same manner as in the first experiment except that a temperature of the substrate support was set to 90° C.

### Experiment Results

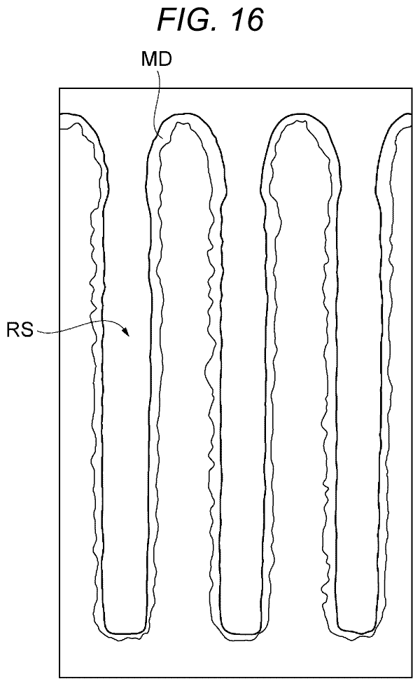

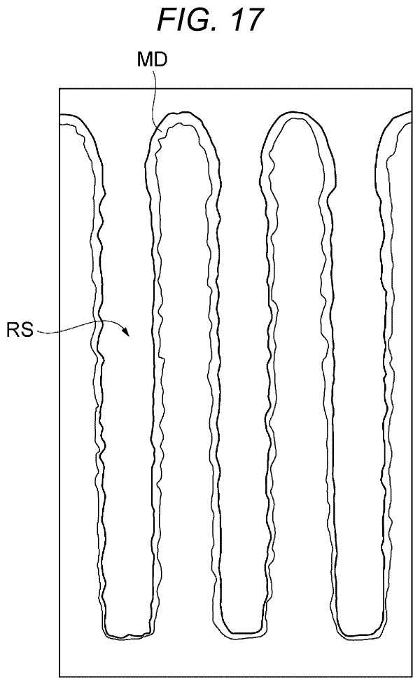

Cross-sections of the substrates obtained in the first experiment and the third experiment were observed. FIG. 16 is a cross-sectional view of an example of the substrate in the first experiment. FIG. 17 is a cross-sectional view of an example of the substrate in the third experiment. As shown in FIGS. 16 and 17, it can be seen in the first experiment and the third experiment that the metal-containing film MD, which is a tungsten-containing film, covers sidewalls, a bottom, and an upper surface of a recess RS.

### Fourth Experiment

A fourth experiment was performed in the same manner as the first experiment, except that a processing time for the step of forming the tungsten-containing film was 2 seconds, a flow rate of the tungsten hexafluoride gas was set to be smaller than that in the first experiment, and the number of cycles was 240.

### Experiment Results

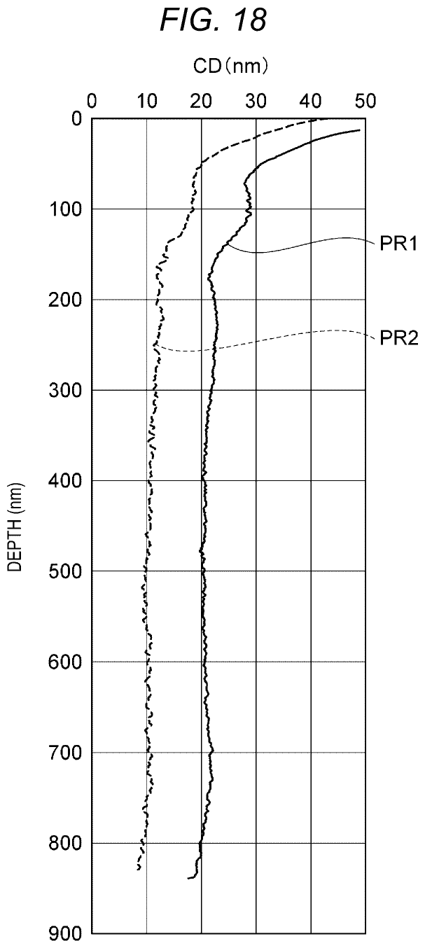

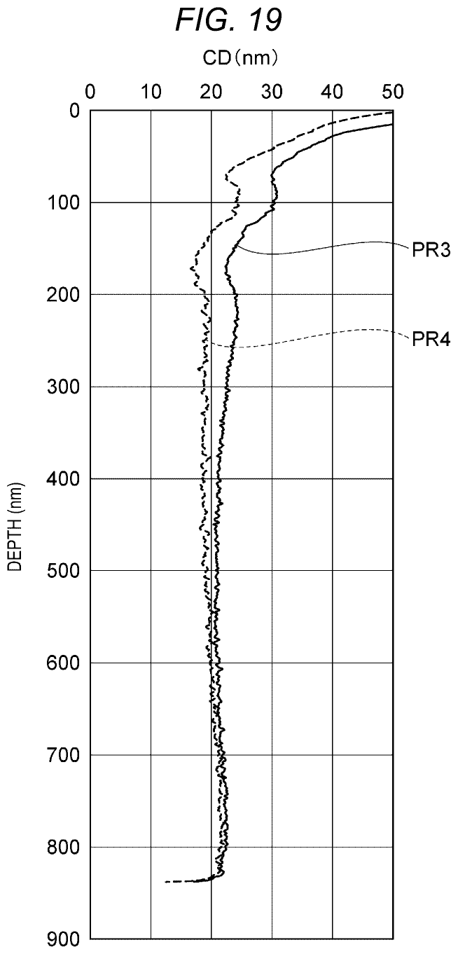

Cross-sections of the substrates obtained in the first experiment and the fourth experiment were observed. In the cross-section, a depth of a recess and a CD of the recess were measured. FIG. 18 is a graph illustrating an example of the depth of the recess and the CD of the recess in the first experiment. FIG. 19 is a graph illustrating an example of the depth of a recess and the CD of the recess in the fourth experiment. In FIG. 18, a profile PR1 shows a surface of the recess before the precursor layer is formed. A profile PR2 shows a surface of the recess after the tungsten-containing film is formed. As illustrated in FIG. 18, in the first experiment, the tungsten-containing film had substantially the same thickness along the sidewall of the recess. In FIG. 19, a profile PR3 shows a surface of the recess before the precursor layer is formed. A profile PR4 shows a surface of the recess after the tungsten-containing film is formed. As shown in FIG. 19, in the fourth experiment, a thickness of the tungsten-containing film became smaller as the recess became deeper. Therefore, it is understood that the thickness of the tungsten-containing film at the bottom of the recess can be reduced by reducing a flow rate of the tungsten hexafluoride gas and shortening a supply time of the tungsten hexafluoride gas.

### Fifth Experiment

In a fifth experiment, a substrate was prepared. An aminosilane gas containing carbon was supplied to the substrate to form a precursor layer on the substrate (step ST2). A processing time of step ST2 was 20 seconds. Next, the precursor layer was modified with a tungsten hexafluoride gas to form a tungsten-containing film (step ST3). A processing time of step ST3 was 10 seconds. Next, the tungsten-containing film was modified with plasma generated from a hydrogen gas (step ST4). A processing time of step ST4 was 10 seconds. Steps ST2 to ST4 were repeated (step ST5). The number of cycles was 270. A temperature of the substrate support was 120° C. Thereafter, the tungsten-containing film on the substrate was etched with plasma generated from a CF₄ gas (step ST6).

### Sixth Experiment

A sixth experiment was performed in the same manner as the fifth experiment except that step ST4 was not performed and duration of step ST3 was 20 seconds.

### Seventh Experiment

A seventh experiment was performed in the same manner as the fifth experiment except that step ST4 was not performed.

### Experiment Results

Cross-sections of the substrates were observed before and after step ST6 in the fifth experiment and the sixth experiment. An etching rate of the tungsten-containing film was measured by measuring a thickness of the tungsten-containing film. The etching rate in the fifth experiment was 31.6 nm/min. The etching rate in the sixth experiment was 47.6 nm/min. Therefore, it is understood that etching resistance of the tungsten-containing film in the fifth experiment is higher than etching resistance of the tungsten-containing film in the sixth experiment.

Before step ST6 in the fifth experiment and the sixth experiment, a composition of the tungsten-containing film was analyzed by X-ray photoelectron spectroscopy (XPS) analysis. In the seventh experiment, a composition of the tungsten-containing film was analyzed by X-ray photoelectron spectroscopy (XPS) analysis. In the fifth experiment to the seventh experiment, the tungsten-containing film contained tungsten, carbon, oxygen, and nitrogen. A composition ratio of the tungsten was the largest. A composition ratio of the carbon was smaller than the composition ratio of the tungsten. A composition ratio of the oxygen was smaller than the composition ratio of the carbon. A composition ratio of the nitrogen was smaller than the composition ratio of the oxygen. The composition ratio of the tungsten contained in the tungsten-containing film in the fifth experiment was larger than the composition ratio of the tungsten contained in the tungsten-containing film in the sixth experiment and the seventh experiment. The composition ratio of the carbon contained in the tungsten-containing film in the fifth experiment was larger than the composition ratio of the carbon contained in the tungsten-containing film in the sixth experiment and the seventh experiment. The composition ratio of the oxygen contained in the tungsten-containing film in the fifth experiment was smaller than the composition ratio of the oxygen contained in the tungsten-containing film in the sixth experiment and the seventh experiment. The composition ratio of the nitrogen contained in the tungsten-containing film in the fifth experiment was smaller than the composition ratio of the nitrogen contained in the tungsten-containing film in the sixth experiment and the seventh experiment. Therefore, it is understood that the composition ratio of the tungsten and the carbon increases by modifying the tungsten-containing film with plasma generated from the hydrogen gas.

### Eighth Experiment

In an eighth experiment, a substrate having a recess was prepared. An aminosilane gas containing carbon was supplied to the substrate to form a precursor layer on the substrate (step ST2). Next, the precursor layer was modified with a tungsten hexafluoride gas to form a tungsten-containing film (step ST3). Next, the tungsten-containing film was modified with plasma generated from a hydrogen gas (step ST4). Steps ST2 to ST4 were repeated (step ST5). The number of cycles was 80.

### Ninth Experiment

A ninth experiment was performed in the same manner as the eighth experiment except that step ST4 was not performed.

### Experiment Results

Cross-sections of the substrates obtained in the eighth experiment and the ninth experiment were observed. As a result, it was confirmed that the tungsten-containing film was formed in the recess. In the cross-section, a depth of a recess and a CD of the recess were measured. In the eighth experiment and the ninth experiment, there was no significant difference in a shape of the recess. Therefore, it is understood in the eighth experiment and the ninth experiment that coverage of the tungsten-containing film formed in the recess is equivalent.

### Tenth Experiment

In a tenth experiment, a substrate having a recess was prepared. An aminosilane gas containing carbon was supplied to the substrate to form a precursor layer on the substrate (step ST2). A processing time of step ST2 was 10 seconds. Next, the precursor layer was modified with a tungsten hexafluoride gas to form a tungsten-containing film (step ST3). A processing time of step ST3 was 5 seconds. Steps ST2 and ST3 were repeated (step ST5). The number of cycles was 100. The temperature of the substrate support was 150° C.

### Eleventh Experiment

An eleventh experiment was performed in the same manner as the tenth experiment except that a temperature of the substrate support was set to 200° C.

### Twelfth Experiment

A twelfth experiment was performed in the same manner as the tenth experiment except that a temperature of the substrate support was set to 250° C.

### Thirteenth Experiment

A thirteenth experiment was performed in the same manner as the tenth experiment except that a temperature of the substrate support was set to 300° C.

### Experiment Results

Cross-sections of the substrates obtained in the tenth experiment to the thirteenth experiment were observed. As a result, it was confirmed in the tenth experiment to the thirteenth experiment that the tungsten-containing film was formed in the recess. A depth of the recess and a CD of the recess were measured. In the tenth experiment to the thirteenth experiment, there was no large difference in a shape of the recess. Therefore, it is understood in the tenth experiment to the thirteenth experiment that coverage of the tungsten-containing film formed in the recess is equivalent. It is understood that the tungsten-containing film becomes thicker as the temperature of the substrate support increases.

In the tenth experiment to the thirteenth experiment, electric resistivity of the tungsten-containing film was measured. The electric resistivity of the tungsten-containing film is calculated by measuring a resistance value of the tungsten-containing film by a four-terminal measurement method and multiplying the obtained resistance value by a thickness of the tungsten-containing film. The electric resistivity of the tungsten-containing film in the tenth experiment was 956.5 μΩ·cm. The electric resistivity of the tungsten-containing film in the eleventh experiment was 413.5 μΩ·cm. The electric resistivity of the tungsten-containing film in the twelfth experiment was 548.0 μΩ·cm. The electric resistivity of the tungsten-containing film in the thirteenth experiment was 443.5 μΩ·cm. The electric resistivity of the tungsten film formed by an ALD method is usually 100 μΩ·cm to 200 μΩ·cm. Therefore, it is understood that the tungsten-containing film in the tenth experiment to the thirteenth experiment has electric resistivity of the same order as the electric resistivity of the tungsten film formed by the ALD method. It is presumed that the electric resistivity of the tungsten-containing film can be further reduced by raising a composition ratio of tungsten in the tungsten-containing film.

While various exemplary embodiments have been described above, various additions, omissions, substitutions, and changes may be made without being limited to the exemplary embodiments described above. In addition, other embodiments may be formed by combining elements in different embodiments.

Hereinafter, various exemplary embodiments in the present disclosure will be described in [E1] to [E20].

### [E1]

A substrate processing method including:
(a) providing a substrate,
(b) supplying a first processing gas containing an amino group and silicon to the substrate to form a first layer on the substrate, and
(c) causing a second processing gas containing a metal halide-containing gas to react with the first layer to form a metal-containing film.

According to the substrate processing method [E1], the first layer can be formed at a lower temperature than when a SiH₄ gas is used in (b). Accordingly, the metal-containing film can be formed at a low temperature.

### [E2]

The substrate processing method according to [E1], further including:
(d) after (c), etching the substrate with plasma generated from a third processing gas.

In this case, the substrate can be etched after the metal-containing film is formed at a low temperature.

### [E3]

The substrate processing method according to [E1] or [E2], in which
the substrate has a recess.

In this case, the metal-containing film can be formed in the recess.

### [E4]

The substrate processing method according to [E3], in which
the recess has a sidewall, a bottom, and an upper surface connected to an upper end of the sidewall, and
before (d), the metal-containing film has a first thickness at the bottom, and has a second thickness at the upper surface, and the first thickness is smaller than the second thickness.

When [E4] is the substrate processing method according to [E2] or [E3] referring back to [E2], the metal-containing film may have the first thickness and the second thickness before (d). In this case, in (d), the recess may be deeper.

### [E5]

The substrate processing method according to any one of [E1] to [E4], in which
the first processing gas contains an aminosilane gas.

### [E6]

The substrate processing method according to any one of [E1] to [E5], in which
the first processing gas contains at least one typical element among hydrogen, boron, carbon, oxygen, nitrogen, phosphorus, and sulfur.

### [E7]

The substrate processing method according to any one of [E1] to [E6], in which
the metal halide-containing gas contains at least one of tungsten, molybdenum, titanium, vanadium, platinum, and cobalt.

### [E8]

The substrate processing method according to any one of [E1] to [E7], in which
in (b), a temperature of a substrate support for supporting the substrate is 300° C. or lower.

### [E9]

The substrate processing method according to [E8], in which the temperature is 150° C. or lower.

### [E10]

The substrate processing method according to any one of [E1] to [E9], further including:
(e) after (c) or between (c) and (d), repeating (b) and (c).

In this case, the metal-containing film can be made thicker.

### [E11]

The substrate processing method according to [E2] or any one of [E3] to [E10] referring back to [E2], further including:
(f) after (d), repeating (b) to (d).

### [E12]

The substrate processing method according to any one of [E1] to [E11], in which
in (c), plasma is generated from the second processing gas.

In this case, the metal-containing film is modified with plasma. For example, an impurity concentration in the metal-containing film can be reduced. Further, a density of the metal-containing film can be improved.

### [E13]

The substrate processing method according to any one of [E1] to [E12], further including:
(g) after (c) or between (c) and (d), modifying the metal-containing film with plasma.

In this case, an impurity concentration in the metal-containing film can be reduced. Further, the density of the metal-containing film can be improved.

### [E14]

The substrate processing method according to [E2] or any one of [E3] to [E13] referring back to [E2], in which
(b) and (c) are performed in a first chamber, and
(d) is performed in a second chamber different from the first chamber.

### [E15]

The substrate processing method according to [E3] or any one of [E4] to [E14] referring back to [E3], in which
a thickness of the metal-containing film is changed in a depth direction of the recess by changing at least one selected from the group consisting of a flow rate of the first processing gas, a flow rate of the second processing gas, a pressure in (b), a pressure in (c), a processing time in (b), and a processing time in (c).

### [E16]

The substrate processing method according to any one of [E1] to [E15], in which
at least one of the first processing gas or the second processing gas contains at least one selected from the group consisting of a hydrogen gas, a SiH₄ gas, a Si₂H₆ gas, a BH₃ gas, and a B₂H₆ gas.

### [E17]

The substrate processing method according to any one of [E1] to [E16], in which
the metal-containing film has electric resistivity of 1000 μΩ·cm or less.

### [E18]

The substrate processing method according to [E17], in which
the metal-containing film has electric resistivity of 100 μΩ·cm to 600 μΩ·cm.

### [E19]

A substrate processing apparatus including:
a chamber,
a substrate support configured to support a substrate in the chamber,
a gas supply configured to supply a first processing gas and a second processing gas into the chamber, the first processing gas containing an amino group and silicon, and the second processing gas containing a metal halide-containing gas, and
a controller configured to control the gas supply to supply the first processing gas to the substrate to form a first layer on the substrate and to cause the second processing gas to react with the first layer to form a metal-containing film.

### [E20]

A plasma processing apparatus including:
a first chamber,
a second chamber,
a substrate support configured to support a substrate in each of the first chamber and the second chamber,
a gas supply configured to supply a first processing gas and a second processing gas into the first chamber and supply a third processing gas into the second chamber, the first processing gas containing an amino group and silicon, and the second processing gas containing a metal halide-containing gas,
a plasma generator configured to generate plasma from the third processing gas in the second chamber, and
a controller configured to control the gas supply and the plasma generator to supply the first processing gas to the substrate to form a first layer on the substrate, to cause the second processing gas to react with the first layer to form a metal-containing film, and after the metal-containing film is formed, to etch the substrate with the plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A substrate processing method comprising:
(a) providing a substrate,
(b) supplying a first processing gas containing an amino group and silicon to the substrate to form a first layer on the substrate, and
(c) causing a second processing gas containing a metal halide-containing gas to react with the first layer to form a metal-containing film.

2. The substrate processing method according to claim 1, further comprising:
after (c), (d) etching the substrate with plasma generated from a third processing gas.

3. The substrate processing method according to claim 1, wherein
the substrate has a recess.

4. The substrate processing method according to claim 3, wherein
the recess has a sidewall, a bottom, and an upper surface connected to an upper end of the sidewall,
the metal-containing film has a first thickness at the bottom and has a second thickness at the upper surface, and
the first thickness is smaller than the second thickness.

5. The substrate processing method according to claim 1, wherein
the first processing gas contains an aminosilane gas.

6. The substrate processing method according to claim 1, wherein
the first processing gas contains at least one typical element among hydrogen, boron, carbon, oxygen, nitrogen, phosphorus, and sulfur.

7. The substrate processing method according to claim 1, wherein
the metal halide-containing gas contains at least one of tungsten, molybdenum, titanium, vanadium, platinum, or cobalt.

8. The substrate processing method according to claim 1, wherein
in (b), a temperature of a substrate support supporting the substrate is 300° C. or lower.

9. The substrate processing method according to claim 8, wherein
the temperature is 150° C. or lower.

10. The substrate processing method according to claim 1, further comprising:
after (c), repeating (b) and (c).

11. The substrate processing method according to claim 2, further comprising:
after (d), repeating (b) to (d).

12. The substrate processing method according to claim 1, wherein
in (c), plasma is generated from the second processing gas.

13. The substrate processing method according to claim 1, further comprising:
after (c), modifying the metal-containing film with plasma.

14. The substrate processing method according to claim 2, wherein
(b) and (c) are performed in a first chamber, and
(d) is performed in a second chamber different from the first chamber.

15. The substrate processing method according to claim 3, wherein
a thickness of the metal-containing film is changed in a depth direction of the recess by changing at least one selected from the group consisting of a flow rate of the first processing gas, a flow rate of the second processing gas, a pressure in (b), a pressure in (c), a processing time in (b), and a processing time in (c).

16. The substrate processing method according to claim 1, wherein
at least one of the first processing gas or the second processing gas contains at least one selected from the group consisting of a hydrogen gas, a SiH₄ gas, a Si₂H₆ gas, a BH₃ gas, and a B₂H₆ gas.

17. The substrate processing method according to claim 1, wherein
the metal-containing film has electric resistivity of 1000 μΩ·cm or less.

18. The substrate processing method according to claim 17, wherein
the metal-containing film has electric resistivity of 100 μΩ·cm to 600 μΩ·cm.

19. A substrate processing apparatus comprising:
a chamber,
a substrate support configured to support a substrate in the chamber,
a gas supply including a first processing gas source and a second processing gas source, the gas supply being configured to supply the first processing gas and the second processing gas into the chamber, the first processing gas containing an amino group and silicon, and the second processing gas containing a metal halide-containing gas, and
circuitry configured to control the gas supply to supply the first processing gas to the substrate to form a first layer on the substrate and to cause the second processing gas to react with the first layer to form a metal-containing film.
